(19) United States
(12) Patent Application Publication
(10) Pub. No.: US 2025/0384932 A1
(43) Pub. Date: Dec. 18, 2025

(54) WORD LINE VOLTAGE MANAGEMENT FOR A MEMORY SYSTEM

(71) Applicant: Micron Technology, Inc., Boise, ID (US)

(72) Inventors: Gowrishankar Gajendiran, Bangalore (IN); Nikhil Garg, Bangalore (IN); Amiya Banerjee, Bangalore (IN)

(21) Appl. No.: 19/233,611

(22) Filed: Jun. 10, 2025

Related U.S. Application Data
(60) Provisional application No. 63/659,449, filed on Jun. 13, 2024.

(51) Int. Cl. G11C 16/10; G11C 16/08; G11C 16/32

(52) U.S. Cl. CPC G11C 16/102; G11C 16/08; G11C 16/32

(57) ABSTRACT

Methods, systems, and devices for word line voltage management for a memory system are described. A memory system may determine a minimum threshold voltage for writing to a block of pages of a memory die, store an indication of the minimum threshold voltage in a first register of the memory die, and transfer the indication of the minimum threshold voltage directly from the first register to a second register of the memory die in response to receiving a first command from a controller. The controller may refrain from transmitting a second command prior to a subsequent write command, where the write command may include one or more additional bits indicating that the memory system is to use the minimum threshold voltage to write data to one or more pages of the block.

### CROSS REFERENCE

The present application for patent claims priority to U.S. Patent Application No. 63/659,449 by Gajendiran et al., entitled “WORD LINE VOLTAGE MANAGEMENT FOR A MEMORY SYSTEM,” filed Jun. 13, 2024, which is assigned to the assignee hereof, and which is expressly incorporated by reference in its entirety herein.

### TECHNICAL FIELD

The following relates to one or more systems for memory, including word line voltage management for a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports word line voltage management for a memory system in accordance with examples as disclosed herein.

FIG. 2 shows an example of a block diagram that supports word line voltage management for a memory system in accordance with examples as disclosed herein.

FIG. 3 shows an example of a block diagram that supports word line voltage management for a memory system in accordance with examples as disclosed herein.

FIG. 4 shows an example of a timing diagram that supports word line voltage management for a memory system in accordance with examples as disclosed herein.

FIG. 5 shows an example of a process that supports word line voltage management for a memory system in accordance with examples as disclosed herein.

FIG. 6 shows a block diagram of a memory system that supports word line voltage management for a memory system in accordance with examples as disclosed herein.

FIG. 7 shows a flowchart illustrating a method or methods that support word line voltage management for a memory system in accordance with examples as disclosed herein.

### DETAILED DESCRIPTION

A memory system may use a minimum threshold voltage (e.g., a minimum dynamic word line start voltage (min-DWLSV)) when performing write operations on memory cells, which may indicate a voltage magnitude to use for applying programming pulses to memory cells in a type of memory block. For example, a memory system may determine the minimum threshold voltage for writing (e.g., data) to a block in response to sampling programming pulses for one or more pages of a first sub-block of the block. The memory system may initially store an indication of the minimum threshold voltage in a first register (e.g., one or more first registers) of the memory die. After storing the minimum threshold voltage (e.g., and prior to performing subsequent write operations to subsequent sub-blocks of the block), a controller external to the memory die (e.g., a managed NAND controller, a memory system controller) may issue a first command (e.g., a get feature command) to transfer (e.g., fetch) the indication of the minimum threshold voltage from the first register to a cache (e.g., RAM, SRAM, DRAM).

Prior to programming each page of each subsequent sub-block of the block, the controller may issue a second command (e.g., a set feature command) to write an indication of the minimum threshold voltage to a second register of the memory die. In some cases, the controller may communicate the first command, the second command, the indication of the minimum threshold voltage, or any combination thereof, via a NAND bus (e.g., an open NAND flash interface (ONFI) bus). In some cases, transferring the indication of the minimum threshold voltage to the controller (e.g., from the first register) and from the controller to the second register may increase a latency associated with each write command of the memory system. Additionally, the first command, second command, the indication of the minimum threshold voltage, or any combination thereof, may use bandwidth in the NAND bus, which may be repurposed for other useful operations. Thus, a system configured to determine a minimum threshold voltage to use for performing writes without decreasing performance at the memory system may be beneficial.

According to techniques described herein, a memory system may determine the minimum threshold voltage for a block of pages of a memory die, store an indication of the minimum threshold voltages in a first register (e.g., of a plurality of first registers) of the memory die, and transfer the indication of the minimum threshold voltage directly from the first register to a second register (e.g., of a plurality of second registers) of the memory die in response to receiving the first command (e.g., the get feature command) from the controller. That is, the memory system may transfer the minimum threshold voltage from the first register of the die to the second register of the die without transferring the indication off-die and without transferring (e.g., routing) the indication to the controller (e.g., without issuing a set feature command). A subsequent write command may include one or more additional bits indicating that the memory system is to use the minimum threshold voltage (e.g., stored to the second register) when performing a write operation on one or more pages of the block. Such operations may reduce or eliminate latency that would have otherwise been incurred due to the issuance of the second command (e.g., the set feature command) prior to each write operation. Additionally, such operations may reduce traffic on the NAND bus associated with transferring both the first and second command, which may increase the available bandwidth of the NAND bus.

In addition to applicability in memory systems as described herein, techniques for word line voltage management for a memory system may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by limiting the use of the second command (e.g., the set feature commando) by a controller for each write command to each page in a memory block and by reducing NAND bus usage, which may reduce a latency for each write (e.g., by about 1.5 microseconds per write operation) and allow for other communications via the NAND bus, among other benefits.

Features of the disclosure are illustrated and described in the context of systems, devices, and circuits. Features of the disclosure are further illustrated and described in the context of memory die diagrams, memory system signaling diagrams, timing diagrams, processes, and flowcharts. In some cases of techniques described herein, an indication of the minimum threshold voltage may be stored in, transferred to, or retrieved from a register. In such contexts (e.g., as well as others), references to a “minimum threshold voltage” (e.g., transferring the minimum threshold voltage, storing the minimum threshold voltage, retrieving the minimum threshold voltage) may be interchangeable with “an indication of the minimum threshold voltage.” Additionally, the term “program” (e.g., program a page, program a memory cell, program a block), as used herein, may be interchangeable with “write data to” (e.g., write data to a page, write data to a memory cell, write data to a block). In some cases, although techniques described herein may be described as being implemented at a first granularity of a memory system (e.g., on a memory system as a whole), techniques described herein may be applied to any granularity of a memory system (e.g., on a memory device, on a memory die).

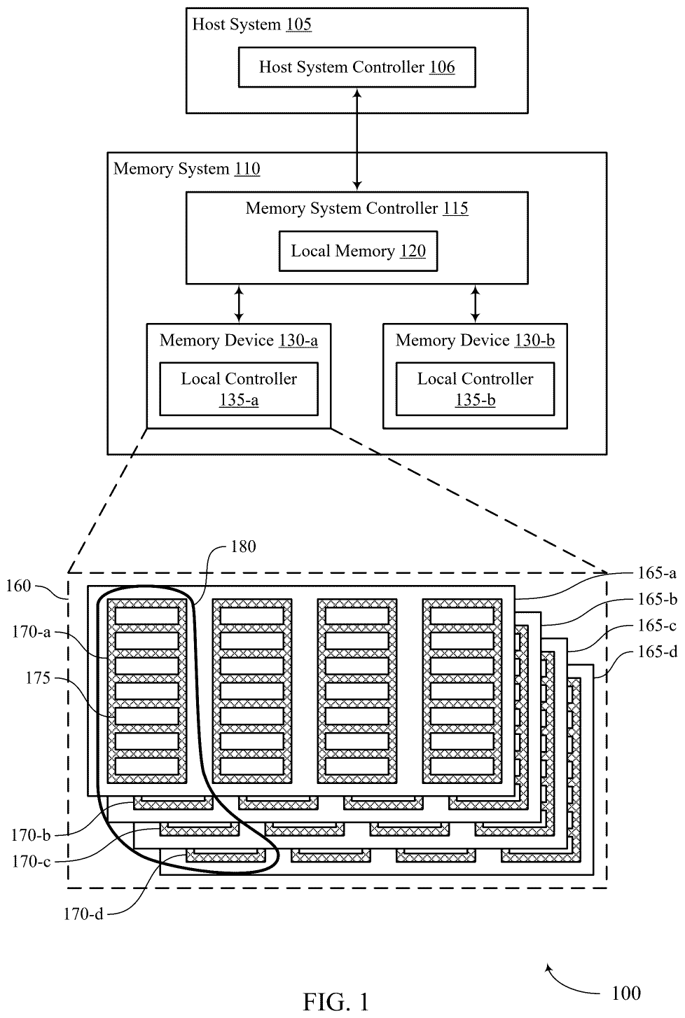

FIG. 1 shows an example of a system 100 that supports word line voltage management for a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an ONFI, and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

According to techniques described herein, a memory system 110 may determine the minimum threshold voltage for a block 170 of pages 175 in a die 160, store an indication of the minimum threshold voltages in a first register (e.g., of a plurality of first registers) of the die 160, and transfer the indication of the minimum threshold voltage directly from the first register to a second register (e.g., of a plurality of second registers) of the die 160 in response to receiving a first command (e.g., the get feature command) from a controller (e.g., local controller 135-a, memory system controller 115). A subsequent write command from the controller may include one or more additional bits indicating that the memory system 110 is to use the minimum threshold voltage (e.g., stored to the second register) when performing operation on one or more pages 175 of the block 170. In some cases, the plurality of second registers may include dedicated registers (e.g., dedicated for storing indications of minimum threshold voltages), general purpose registers (e.g., scratch-pad registers), or a combination thereof. Such operations may reduce or eliminate latency resulting that would have otherwise been incurred due to the issuance of the second command (e.g., the set feature command) prior to each write operation. Additionally, such operations may reduce traffic on the NAND bus associated with transferring both the first and second command, which may increase the available bandwidth of the NAND bus.

The system 100 may include any quantity of non-transitory computer readable media that support word line voltage management for a memory system. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

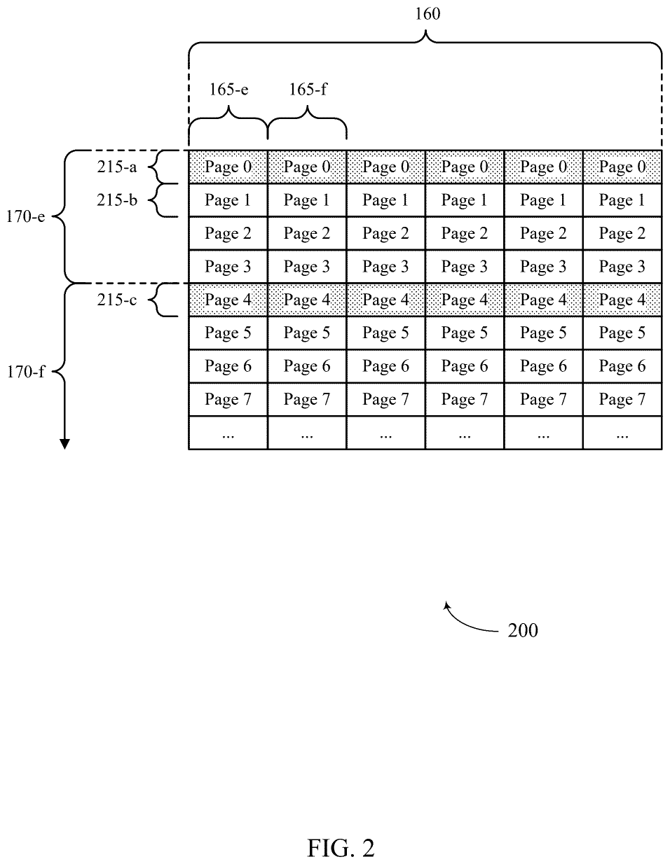

FIG. 2 shows an example of a block diagram 200 that supports word line voltage management for a memory system in accordance with examples as disclosed herein. In some cases, aspects of the block diagram 200 may implement or be implemented by aspects of FIG. 1. For example, the block diagram 200 may include a die 160, one or more different planes 165 (e.g., a plane 165-c, a plane 165-f), one or more blocks 170, and one or more pages of memory cells (e.g., NAND cells), which may be examples of the dies 160, planes 165, blocks 170, and pages 175, respectively, as described herein with respect to FIG. 1. The block diagram 200 may further include one or more sub-blocks 215, where each sub-block 215 may include a set of pages included in a word line of the die 160 (e.g., a corresponding page of each plane 165 of the die 160). In some aspects, the memory die diagram 200 may illustrate a device that may perform the techniques described herein for word line voltage management, which may reduce latency and NAND bus traffic associated with writing data to a die 160 of a memory device 130 by transferring a minimum threshold voltage from a first register directly to a second register within the die 160 in response to a first command (e.g., a get feature command).

In some memory systems, memory cells that have experienced a relatively high quantity of program and erase cycles (e.g., cycled memory cells, end of life memory cells) may be relatively easier to program (e.g., have a decreased programming time (e.g., tPROG), easier to write data to, program with less voltage, program with less programming pulses) than memory cells that have experienced a relatively low quantity of program and erase cycles (e.g., fresh memory cells). In some cases, a manufacturer may configure one or more programming parameters (e.g., default program trims from a factory) of a memory system to accommodate cycled memory cells, which may reduce possible damage to the memory system associated with aggressive programming (e.g., using a relatively high voltage, programming for a relatively long duration). Such programming parameters may include a relatively low (e.g., conservative) threshold voltage (e.g., programming voltage, word line start voltage (WLSV)) for programming fresh memory cells, which may result in longer programming times (e.g., an increased tPROG, increased programming latency) for the fresh memory cells.

In some cases, a memory system may dynamically adjust (e.g., increase) the threshold voltage during page programming to decrease programming times for a block 170 with fresh memory cells. For example, by increasing the threshold voltage for fresh memory cells (e.g., when compared to a threshold voltage used for cycled memory cells), the programming times for fresh memory cells and cycled memory cells may be relatively similar. Accordingly, a write performance of the memory system may be relatively faster and more uniform.

In one example, if the memory system initiates programming of the block 170-c (e.g., including pages 0-3 for each plane 165 of the die 160), the memory system may issue a write command to each page of a sub-block 215-a (e.g., a first sub-block 215 of the block 170-c, the first page within the block 170-e of each plane 165 of die 160) and may sample a quantity of programming pulses used to program each page of the sub-block 215-a. After storing information (e.g., data) associated with the sampling, the memory system (e.g., a memory device including the die 160) may dynamically adjust (e.g., determine) the threshold voltage for pages of subsequent sub-blocks 215 (e.g., including a sub-block 215-b) of the block 170-e (e.g., the first word line) according to the stored information. In cases where the die 160 has a plurality of planes 165 (e.g., multi-plane programming), the stored information may include a threshold voltage used to program a page of the sub-block 215-a that used a minimum quantity of programming pulses (e.g., requires the least amount of programming pulses to be programmed). Thus, the memory system may dynamically adjust a threshold voltage used to program each block 170 (e.g., each word line) of the die 160.

The memory device may store the information for one of the blocks 170 (e.g., a block 170 that is currently being programmed) at a time. Thus, to write to a block 170-f (e.g., a new block, if a firmware moves from programming the block 170-c to programming the block 170-f), the memory system may clear the stored information, sample the sub-block 215-c (e.g., the first sub-block 215 of the block 170-f), store information associated with sampling the sub-block 215-c, and adjust (e.g., determine) a threshold voltage for the block 170-f according to the information. Thus, the memory system may save and manage the threshold voltage for an open block (e.g., a block 170 that is currently being programmed).

In some cases, a memory system may support a feature for determining and storing a minimum threshold voltage (e.g., a minimum dynamic word line start voltage (min-DWLSV), a programming voltage) for each of one or more types of the blocks 170 in the die 160. To support such a feature, the memory system may include a plurality of first registers (e.g., one or more first registers) that includes a respective register for storing a minimum threshold voltage for each block type of the die 160. In some cases, the plurality of registers may store the information (e.g., the minimum threshold voltage) for a block 170 after the memory system performs a write on a first sub-block 215 of the block 170 (e.g., as described herein). In some cases, the plurality of first registers may include one or more dedicated registers (e.g., registers of the die 160 dedicated to storing the minimum threshold voltages, or otherwise dedicated for a specific purpose), one or more general purpose registers (e.g., scratchpad registers, registers that the memory system may use for a period for storing the minimum threshold voltages, or otherwise not dedicated for a specific purpose and available for general purposes), or both. Additionally, or alternatively, the plurality of first registers may be accumulate registers without other capabilities (e.g., no other intelligence, capable of accumulating and updating the minimum threshold voltage).

In some cases, each first register of the plurality of first registers may correspond to a block type included in the die 160. For example, the die 160 may include a plurality of blocks 170 of varying block types, including one or more of static blocks, dynamic blocks, high endurance (HE) blocks, or other block types. A block type may indicate information about a cell type of one or more memory cells included in the block 170. For example, at a given time, a cell type of memory cells in a block 170 may include one of SLCs, MLCs, TLCs, QLCs, or any other kind of memory cell, and the cell type may change (e.g., be dynamic) or be fixed.

In one example, a first register of the plurality of first registers may store a minimum threshold voltage for static blocks (e.g., blocks 170 that include memory cells of a fixed cell type). A second register of the plurality of registers may store a minimum threshold voltage for dynamic blocks (e.g., blocks 170 which include cells that may switch cell types (e.g., dynamic cells)), and a third register of the plurality of registers may store a minimum threshold voltage for HE blocks (e.g., blocks which include HE SLC memory cells). Thus, the memory system may store (e.g., track) at least one minimum threshold voltage for each type of block 170 in each die 160. In some cases, each register of the plurality of first registers may save the minimum threshold voltages for a respective block type while programming a different type of block 170. Additionally, or alternatively, a power cycle or reset of the memory system may clear the plurality of first registers.

In some cases, to utilize the minimum threshold voltages stored in the plurality of first registers, a controller of the memory system (e.g., memory system controller 115, local controller 135) may communicate one or more commands to the die 160. In some cases, the controller may communicate the command via a bus (e.g., a NAND bus). For example, to write data to the block 170-e, the controller may issue a first command (e.g., a get feature command) after programming the sub-block 215-a and storing the minimum threshold voltage to a register of the plurality of first registers. The first command may request (e.g., fetch) the minimum threshold voltage from a register of the plurality of first registers into a cache memory (e.g., RAM, SRAM, DRAM). The controller may also issue a second command (e.g., a set feature NAND command) to set (e.g., store) the received minimum threshold voltage (e.g., or an indication thereof) from the cache memory to a second register associated with the die 160 (e.g., the second register not being of the plurality of first registers). The memory device that includes the die 160 may then use the minimum threshold voltage in the second register to program one or more pages of the block 170-c.

In some cases (e.g., when block bouncing), to program a plurality of pages of a plurality of the blocks 170 of the die 160, the controller may issue the first command once per block 170, and may issue the second command once per page of each block 170. For example, to prevent re-sampling (e.g., re-determining the minimum threshold voltage) associated with a block 170, the controller may issue the second command for any NAND block address change (e.g., excepting virtual blocks) within the block 170, which may include switching between different planes 165, between different sub-blocks 215, or both, of the block 170. After issuing the second command to set the minimum threshold voltage in the second register for a page, the controller may issue a write command for one or more pages of the die 160, and the memory device may perform a write operation on the one or more pages using the minimum threshold voltage in the second register in accordance with the write command. The controller may follow similar operations (e.g., issuing the first command once per block to fetch a minimum threshold voltage to the cache memory and issuing the second command once per page to set the minimum threshold voltage from the cache memory to the second register) for each subsequent block 170 to be programmed in the die 160.

In some cases, issuing the second command (e.g., the set feature command, and performing the related actions) before issuing each write command for each page may increase a latency associated with writing to the die 160. Additionally, transferring the minimum threshold voltage from the plurality of first registers to the cache memory (e.g., according to the first command) and from the cache memory to the second register (e.g., according to the second command) to program each page of the block 170 may use a relatively high amount of bandwidth associated with the NAND bus (e.g., from the controller or cache memory to the memory device that includes the dies 160).

According to techniques described herein, a memory device that includes the die 160 may determine a minimum threshold voltage for a block 170 of pages, store an indication of the minimum threshold voltages in a first register (e.g., not shown in FIG. 2) within the die 160, and transfer the indication of the minimum threshold voltage directly from the first register to a second register (e.g., not shown in FIG. 2) of the die 160 in response to receiving the first command from a controller (e.g., local controller 135-a, memory system controller 115). Such operations may reduce or eliminate the use of the second command, reducing a latency resulting from the second command associated with setting the minimum threshold voltage to the second register prior to each write operation.

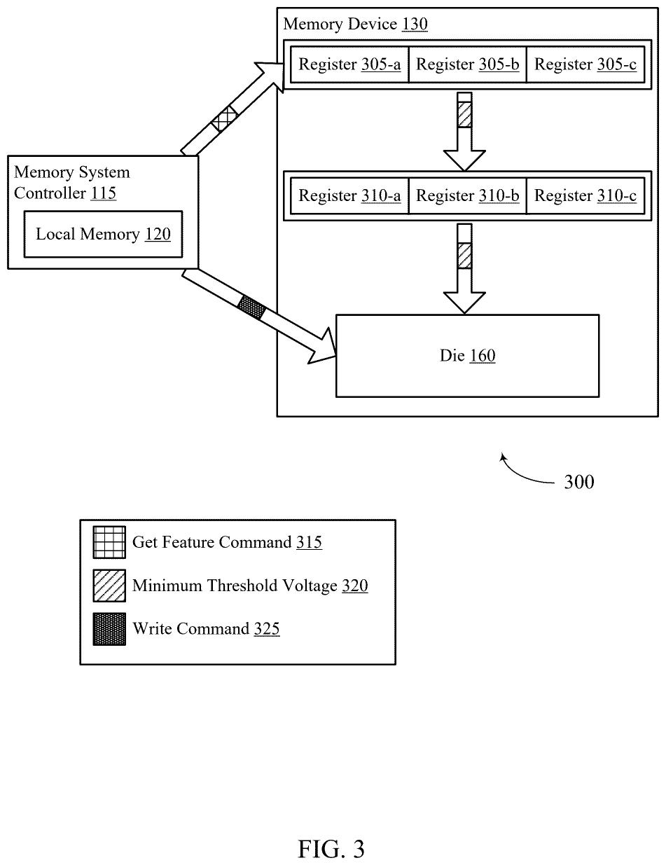

FIG. 3 shows an example of a block diagram 300 that supports word line voltage management for a memory system in accordance with examples as disclosed herein. In some cases, aspects of the diagram 300 may implement or be implemented by aspects of FIGS. 1 and 2. For example, the block diagram 300 may include a memory system controller 115, which may be an example of the memory system controller 115 or the local controllers 135 as described herein with respect to FIGS. 1 and 2. The block diagram 300 may also include a memory device 130, which may be an example of the memory devices 130 or a die 160 as described herein with respect to FIGS. 1 and 2.

The block diagram 300 may further include registers 305 (e.g., an example of the plurality of first registers as described herein with respect to FIG. 2), local memory 120 (e.g., an example of the local memory 120 or a memory of the local controllers 135 as described herein with respect to FIG. 1, an example of the cache memory as described herein with respect to FIG. 2), a die 160 (e.g., an example of the dies 160 described herein with respect to FIGS. 1 and 2), minimum threshold voltages 320 (e.g., examples of the minimum threshold voltages described herein with respect to FIGS. 1 and 2), and a get feature command 315 (e.g., an example of the first command described herein with respect to FIG. 2). In some aspects, the memory system signaling diagram 300 may illustrate signaling within a memory system to accomplish word line voltage management as described herein, which may reduce latency and NAND bus traffic associated with writing data to the die 160 of the memory device 130 by transferring the minimum threshold voltage 320 from a register 305 directly to a register 310 (e.g., within the die 160) in response to receiving the get feature command 315 from the memory system controller 115.

In some cases, the memory device 130 may include the registers 305 and registers 310 for storing minimum threshold voltages, where each of the registers 305 and each of the registers 310 may correspond to (e.g., store a minimum threshold voltage for) a respective block type of the die 160. In one example, a register 305-a and a register 310-a may correspond to static blocks of the die 160, a register 305-b and a register 310-b may correspond to dynamic blocks of the die 160, and a register 305-c and a register 310-c may correspond to HE blocks of the die 160. Each of the registers 305 and the registers 310 may be a general purpose register (e.g., a scratch pad register) or a dedicated register, as described herein with respect to FIG. 2. With respect to the description of FIG. 2, the registers 310 may include the second register and one or more (e.g., two) additional registers (e.g., 8-bit registers, scratchpad registers, dedicated registers). That is, the memory device 130 may allocate an additional quantity of bits (e.g., 16 bits) of the registers for storing the minimum threshold voltages 320 within the memory device 130.

Although a quantity of registers 305, registers 310, and dies 160 are shown in the memory system signaling diagram 300, the techniques described herein may anticipate any quantity of registers 305, registers 310, dies 160, or any other component of the memory device 130 or the memory system controller 115. Additionally, each die 160 of the memory device 130 may correspond to a respective set of the registers 305 and the registers 310, each set including a register 305 and a register 310 for each block type included in each die 160.

According to techniques described herein, the memory device 130 may save minimum threshold voltages 320 for each block type of a die 160 in the registers 310 of the memory device 130 in response to the memory system controller 115 issuing the get feature command 315 to the registers 305. Such actions may be performed instead of storing a minimum threshold voltage 320 in the local memory 120 (e.g., a firmware, the cache memory) after issuing the get feature command 315, as described herein with respect to FIG. 2. In some cases, such actions may reduce latency associated with transferring data between the memory device 130 and the memory system controller 115 for each write command and may deprecate the use of a second command (e.g., set feature NAND command) before issuing each write command.

For example, the registers 305 (e.g., the plurality of first registers, registers 8Bh P1, P2, and P3) may store the minimum threshold voltages 320 for each block type of the die 160 after the sampling described herein with respect to FIG. 2. In response to issuing the get feature command 315 to the memory device 130 (e.g., via the NAND bus), the memory device 130 may fetch (e.g., transfer) one or more of the minimum threshold voltages 320 from the registers 305 to the registers 310. In some cases, the get feature command 315 may be associated with a write operation (e.g., a next write operation) associated with a first block type, and may fetch a minimum threshold voltage 320 from a register 305 associated with the first block type to a register 310 associated with the first block type.

Subsequently, the memory system controller 115 may issue a write command 325 to the memory device 130 (e.g., via the NAND bus) without issuing the second command described herein with respect to FIG. 2. In some cases, the memory device 130 may perform the write operation associated with the write command 325 to the one or more blocks of the die 160 using the minimum threshold voltage 320 stored in the registers 310 (e.g., in a register 310 associated with a block type of the one or more blocks of the die 160).

In some cases, the write command 325 may indicate for the memory device 130 to use the minimum threshold voltage 320 from a register 310 for the write operation. For example, the write command 325 may include one or more additional bits, where different values of the one or more additional bits may indicate one or more of whether to use the minimum threshold voltages 320 from the registers 310, which register 310 from which to use the minimum threshold voltages 320 for the write operation, and whether or not to re-sample a block for the minimum threshold voltages 320 to store in the registers 305 (e.g., as described herein with respect to FIG. 2). In an example where the memory device 130 includes three of the registers 310, the one or more additional bits may include two bits, where the values of ‘00’, ‘01’, and ‘10’ may indicate for the memory device 130 to use the minimum threshold voltage indicated by the register 310-a, the register 310-b, and the register 310-c, respectively, and the value of ‘11’ may indicate for the memory device 130 to re-sample the threshold minimum voltage for the one or more blocks associated with the write command 325.

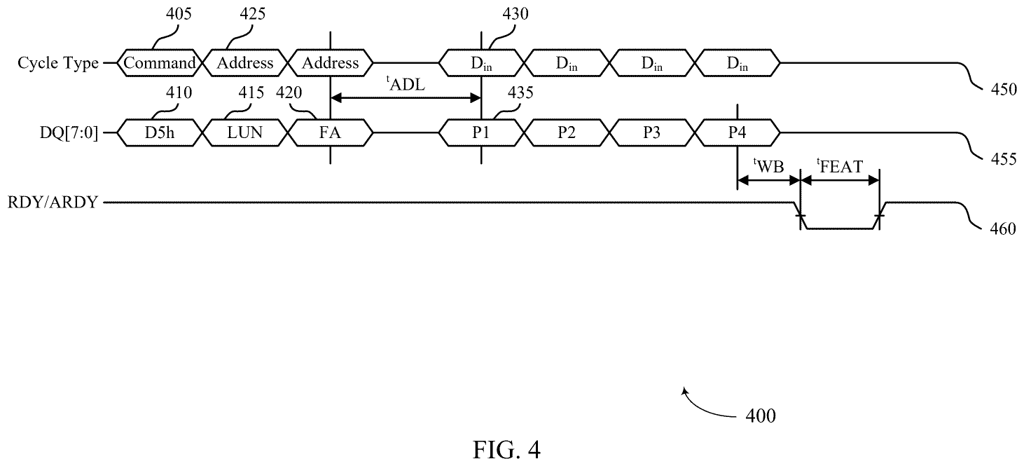

A memory system implementing the techniques described herein may experience one or more advantages including improved overall system performance. For example, the techniques described herein may reduce a latency associated with each write operation by a duration (e.g., 1.5 microseconds, as described herein with respect to FIG. 4), reduce usage of bandwidth of the NAND bus between the memory system controller 115 and the memory device 130, reduce power usage of the memory system by reducing communications between the memory system controller 115 and the memory device 130 (e.g., via an ONFI), and reduced complexity associated with command scheduling for the memory system controller 115. In some aspects, the techniques described herein may apply to memory systems capable of SLC, TLC, QLC, or any memory cell type.

FIG. 4 shows an example of a timing diagram 400 that supports word line voltage management for a memory system in accordance with examples as disclosed herein. In some cases, aspects of the timing diagram 400 may illustrate a time savings that may be achieved by implementing one or more aspects of FIGS. 1-3. For example, the timing diagram 400 may illustrate a set feature command (e.g., set feature NAND command) which may be an example of the second command as described herein with respect to FIGS. 2 and 3. By implementing techniques described herein, a memory system may reduce or otherwise eliminate usage of the set feature command illustrated in the timing diagram 400, which may reduce latency and NAND traffic associated with performing write operations to a memory die.

For example, the additional one or more bits in the write command 325 (e.g., as described herein with respect to FIG. 3) may reduce or otherwise eliminate the need for the set feature command. For example, the one or more additional bits of the write command may specify whether a memory device is to use the minimum threshold voltage from the registers 310 (e.g., as described herein with respect to FIG. 3), which may reduce the quantity of instances that the memory device sets the minimum threshold voltage to the registers 310. In some cases, reducing the usage of the set feature command may reduce the latency inculcated into a write operation due to a controller (e.g., the controllers 115, the controllers 135, as described herein) issuing the set feature command before each write command.

The timing diagram 400 may include a cycle type timeline 450, a data timeline 455, and an array ready (RDY/ARDY) timeline 460. In some cases, the data timeline 455 may show one or more commands or transmissions communicated via the NAND bus (e.g., an ONFI bus) between a controller (e.g., memory system controller 115) and a memory device (e.g., memory device 130, a die 160), and the RDY/ARDY timeline 460 may show a value of an RDY/ARDY line associated with the memory device.

In some cases, the memory device may enter a command cycle 405 and the controller may transmit a D5h command 410 (e.g., an example of the set feature command) with an accompanying logical unit number (LUN) 415 and feature address (FA) 420 during one or more address cycles 425. In some cases (e.g., in legacy techniques), the LUN 415 and the FA 420 may indicate the second register to which the minimum threshold voltage is set from the cache memory (e.g., RAM, SRAM, DRAM) of the memory system (e.g., as described herein with respect to FIG. 2). After waiting a time ^{t}ADL that is associated with transmitting the set feature command (e.g., waiting for the minimum threshold voltage to be set to the second register), the cycle type for the memory device may enter a data in (Din) cycle 430 for one or more cycles, and the controller may transmit one or more data signals 435 (e.g., P1, P2, P3, P4) to the memory device. After transmitting the data signals 435, the RDY/ARDY line may wait for a duration ^{t}WB before indicating that the memory device (e.g., an array of the memory device, a die) is not ready (e.g., moving to a low value) for a duration ^{t}FEAT.

In some cases, various delay durations associated with the set feature command may cause relatively high latency for each write command. For example, depending on the FA 420 associated with the set feature command, ^{t}FEAT may have one of a plurality of values (e.g., ^{t}FEAT1 of 1 microsecond, ^{t}FEAT2 of 3 microseconds, ^{t}FEAT3 of 4 microseconds). ^{t}ADL and ^{t}WB may also be associated with communicating the set feature command and may have typical corresponding values (e.g., 150 nanoseconds and 80 nanoseconds, respectively). Additionally, transmitting the set feature command may be associated with a scheduling delay, which may have a corresponding value (e.g., approximately 770 nanoseconds). Thus, a total latency per write operation associated with the set feature command (e.g., summing ^{t}FEAT, ^{t}ADL, ^{t}WB, and the scheduling delay) may be significant (e.g., at least approximately 1.5 microseconds, assuming the lowest value for ^{t}FEAT). Thus, implementing the techniques described herein may reduce a latency associated with each write command by a relatively high duration of time, and may include allocating an additional quantity of bits in a memory device to store the minimum threshold voltages for write operations.

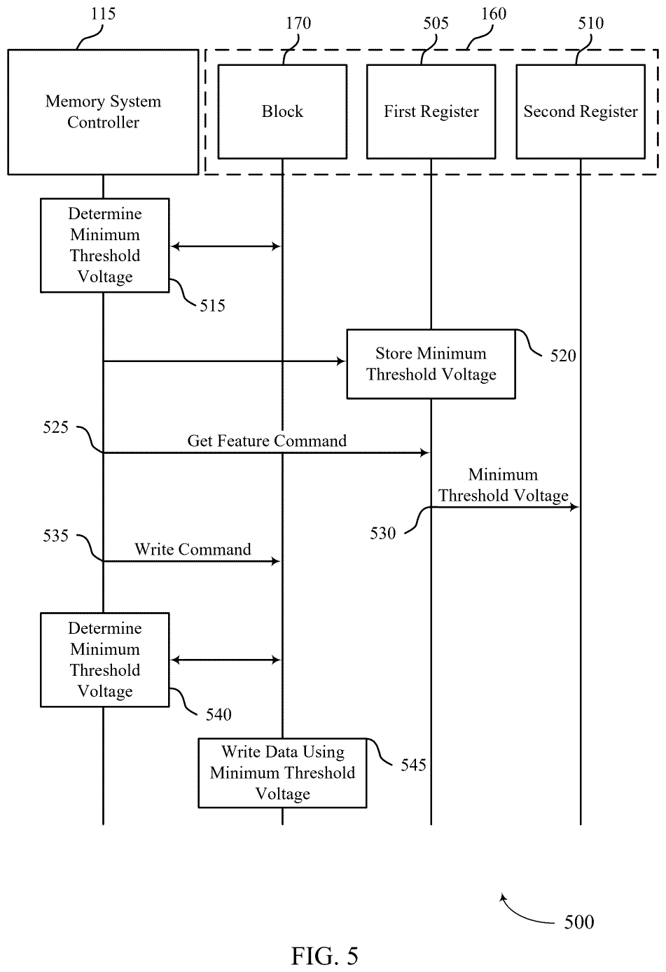

FIG. 5 shows an example of a flow 500 that supports word line voltage management for a memory system in accordance with examples as disclosed herein. In some cases, aspects of the flow 500 may implement or be implemented by aspects of FIGS. 1-4. For example, the flow 500 may include a memory system controller 115, which may be an example of the memory system controller 115, the local controller 135, or a combination thereof, as described herein with respect to FIGS. 1-4. Additionally, the flow 500 may include a die 160, which may be an example of the dies 160, the memory devices 130, or a combination of both (e.g., a memory die 160 in a memory device 130) as described herein with respect to FIGS. 1-4. Additionally, the flow 500 may include a block 170 (e.g., an example of the blocks 170 as described herein with respect to FIGS. 1-4), a first register 505 (e.g., an example of the first registers and registers 305 as described herein with respect to FIG. 1-4) and a second register 510 (e.g., an example of the second registers and registers 310 as described herein with respect to FIGS. 1-4). In some aspects, the die 160 may determine and store a minimum threshold voltage, and may write data to at least one page of the block 170 within the die 160 using the minimum threshold voltage without transferring the minimum threshold voltage outside of the memory device 130 (e.g., to an external controller such as the memory system controller 115) and without receiving a command to set the minimum threshold in the second register 510.

In the following description of flow 500, the operations may be performed in a different order than the order shown, or other operations may be added or removed from the flow 500. For example, some operations may also be left out of flow 500, may be performed in different orders or at different times, or other operations may be added to flow 500. Although the memory system controller 115 and the die 160 are shown performing the operations of flow 500, some aspects of some operations may also be performed by one or more other devices.

Some aspects of the flow 500 may be implemented as instructions stored in one or more memories (e.g., firmware stored in one or more memories coupled with the die 160 or the memory system controller 115). For example, the instructions, when executed by one or more controllers (e.g., the memory system controller 115, a local controller 135), may cause the one or more controllers (or a device or a system) to perform the operations of the process flow 500. In some cases, operations of the flow 500 for which the memory system controller 115 is responsible may be implemented in instructions stored in local memory 120 or a memory device 130 and executed by the memory system controller 115 or a local controller 135. Similarly, operations in the flow 500 for which the die 160 is responsible may be implemented in instructions stored in the die 160, in a memory device 130, in a memory system 110, or a combination therein, and may be executed by a local controller 135 or another controller associated with the die 160.

At 515, a minimum threshold voltage for writing to a page of memory cells may be determined. For example, the memory system controller 115 may determine the minimum threshold voltage. In some cases, the minimum threshold voltage may be associated with writing data (e.g., write operations) to one or more pages of memory cells within the block 170 of memory cells (e.g., a first page of each word line of memory cells within the block). In some cases, the block 170 may include a plurality of pages of memory cells, and may be associated with (e.g., span) one or more planes of the die 160 (e.g., as described herein with respect to FIG. 2), where one or more sub-blocks of the block 170 may each include at least a page from each plane.

In some cases, determining the minimum threshold voltage may include determining a minimum quantity of programming pulses for writing to one or more pages of a first sub-block of the block 170 (e.g., to a first page of the block 170 in one or more planes associated with the block 170, as described herein with respect to FIG. 2). For example, the memory system controller 115 may issue write operations for the one or more pages in the first sub-block of the block 170. The memory system controller 115 may sample a quantity of programming pulses used to complete the write operations to the one or more pages of the first sub-block and determine the minimum threshold voltage according to the sampled quantities of programming pulses. For example, the memory system controller 115 may determine the minimum threshold voltage to be a voltage used to program a first page of the one or more pages that is associated with the fewest programming pulses (e.g., a minimum quantity of programming pulses).

At 520 an indication of the minimum threshold voltage may be stored. For example, the memory system controller 115 may store the indication of the minimum threshold value to the first register 505 (e.g., a register 8Bh). In some cases, the first register 505 may store the indication to the first register in response to the memory system controller 115 determining the minimum threshold voltage. For example, after writing data to a last page of the one or more pages of the first sub-block (e.g., and after performing the sampling), the first register 505 may store the indication. In some cases, the first register 505 may be a dedicated register (e.g., dedicated for storing indications of minimum threshold voltages) or a general purpose register (e.g., a scratchpad register) that the die 160 may use to store the indication. The first register may be one of a plurality of first registers, where each first register 505 may correspond to (e.g., hold a minimum threshold voltage associated with) a block type of a plurality of blocks included in the die 160.

At 525, a command may be issued. For example, the memory system controller 115 (e.g., a controller external to the memory die) may issue (e.g., transmit) the command (e.g., a get feature command) to the first register 505. In some cases, the command may include a single command, and the command may indicate the die 160 to transfer the minimum threshold voltage directly from the first register 505 to a second register 510. For example, the single command may be a get feature command associated with the minimum threshold voltage.

At 530, the indication of the minimum threshold voltage may be transferred from the first register 505 to the second register 510. For example, the memory die 160 may transfer (e.g., within the die 160) the indication of the minimum threshold voltage from the first register 505 to the second register 510. In some cases, the die 160 may transfer the indication directly from the first register 505 to the second register 510 in response to receiving the command (e.g., the single command) issued to the die 160 by the memory system controller 115. For example, the die 160 may transfer the indication of the minimum threshold voltage directly from the first register 505 to the second register 510 without the indication of the minimum threshold voltage being transferred to the memory system controller 115. In some cases, the second register 510 may be of a plurality of second registers of the die 160. Similar to the plurality of first registers, each second register 510 of the plurality of second registers (e.g., including the second register 510) may be associated with a respective minimum threshold voltage for a respective block type included in the die 160. In some cases, the second register 510 may be a dedicated register or a general purpose register that the die 160 may use to store the indication.

At 535, a write command may be issued. For example, the memory system controller 115 (e.g., the controller external to the memory die) may issue the write command to the die 160, a memory device that includes the die 160, or one or more components of the die 160 (e.g., the block 170). In some cases, the write command may include one or more bits (e.g., additional bits, dedicated bits), which may indicate for the die 160 to use the minimum threshold voltage indicated by the second register 510. In one example, the one or more additional bits may be one bit that enables the die 160 to retrieve the minimum threshold voltage from the second register 510 (e.g., for completing the write command) without receiving a second command (e.g., a set feature command, as described herein with respect to FIG. 4). In another example, the one or more bits may include a plurality of bits, and the die 160 may determine a type of the block 170 (e.g., a block type) that includes the one or more pages associated with the write command in response to a first value of the one or more bits indicating the die 160 to use the minimum threshold voltage for the type of the block (e.g., as described herein with respect to FIG. 3).

In some cases, at 540, a value of the minimum threshold voltage may be determined (e.g., redetermined). For example, the memory system controller 115 may determine the minimum threshold voltage for writing to the one or more pages of memory cells within the memory die (e.g., for a second time, after determining the minimum threshold voltage at 515) in response to a second value of the one or more bits indicating the memory system controller 115 to do so (e.g., as described herein with respect to FIG. 3). In some cases, the memory system controller 115 may configure the one or more bits to be the second value in response to detecting an error in the minimum threshold value, detecting an unavailability of the second register 510 to store the minimum threshold voltage, or both.

At 545 data may be written to the plurality of pages of the block 170. For example, data may be written to the block 170 based on the write command issued at 535 using the minimum threshold voltage (e.g., as indicated by the second register 510). In some cases, writing the data to the plurality of pages may include applying one or more programming pulses to one or more memory cells associated with one or more pages of the plurality of pages, where the programming pulses may have a magnitude of the threshold voltage level. Additionally, or alternatively, the data may be written to one or more pages of one or more planes of the block 170 without receiving a second command (e.g., a set feature command) from the memory system controller 115 in between writes.

According to these techniques, write operations may be performed with reduced latency and reduced NAND bus traffic. For example, by transferring the minimum threshold voltage directly from the first register 505 to the second register 510 (e.g., without transmitting the indication of the minimum threshold voltage to an external controller such as the memory system controller 115), write latency and NAND bus traffic may be reduced. Additionally, multiple write operations may be performed without receiving the second command (e.g., the set feature command) from the memory system controller 115, which may further reduce latency and NAND bus traffic associated with write operations to the block 170.

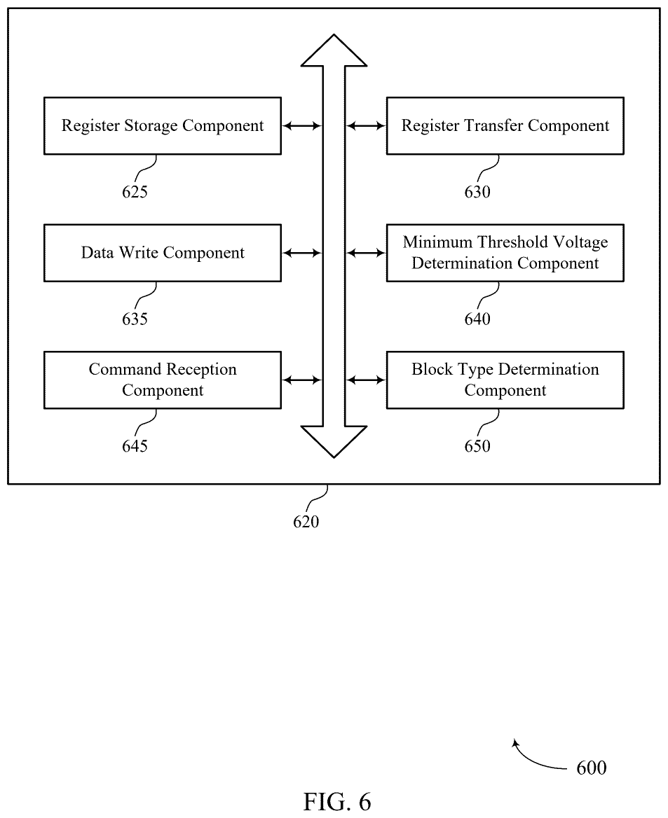

FIG. 6 shows a block diagram 600 of a memory system 620 that supports word line voltage management for a memory system in accordance with examples as disclosed herein. The memory system 620 may be an example of aspects of a memory system as described with reference to FIGS. 1 through 5. The memory system 620, or various components thereof, may be an example of means for performing various aspects of word line voltage management for a memory system as described herein. For example, the memory system 620 may include a register storage component 625, a register transfer component 630, a data write component 635, a minimum threshold voltage determination component 640, a command reception component 645, a block type determination component 650, or any combination thereof. Each of these components, or components of subcomponents thereof (e.g., one or more processors, one or more memories), may communicate, directly or indirectly, with one another (e.g., via one or more buses).

The register storage component 625 may be configured as or otherwise support a means for storing, to a first register within a memory die of the memory system, an indication of a minimum threshold voltage for writing to a page of memory cells within the memory die, where the page is within a block including a plurality of pages. The register transfer component 630 may be configured as or otherwise support a means for transferring, within the memory die, the indication of the minimum threshold voltage from the first register to a second register within the memory die in accordance with a command issued to the memory die by a controller external to the memory die. The data write component 635 may be configured as or otherwise support a means for writing data to the plurality of pages of the block using the minimum threshold voltage after transferring the indication to the second register and in response to a write command issued to the memory die by the controller external to the memory die.

In some examples, the minimum threshold voltage determination component 640 may be configured as or otherwise support a means for determining the minimum threshold voltage for writing to the page of memory cells within the memory die in response to writing to a first page of a word line within the block, where storing the indication to the first register is in response to determining the minimum threshold voltage.

In some examples, to support determining the minimum threshold voltage, the minimum threshold voltage determination component 640 may be configured as or otherwise support a means for determining a minimum quantity of programming pulses for writing to the first page of the word line within the block.

In some examples, the command reception component 645 may be configured as or otherwise support a means for receiving, by the memory die, the write command issued by the controller external to the memory die, where the write command includes one or more bits indicating to use the minimum threshold voltage.

In some examples, the second register is included in a plurality of registers that are each associated with a respective minimum threshold voltage for a respective block type.

In some examples, the block type determination component 650 may be configured as or otherwise support a means for determining a type of the block in response to a first value of the one or more bits indicating to use the minimum threshold voltage for the type of the block.

In some examples, the minimum threshold voltage determination component 640 may be configured as or otherwise support a means for determining, for a second time, the minimum threshold voltage for writing to the page of memory cells within the memory die in accordance with a second value of the one or more bits.

In some examples, to support transferring the indication of the minimum threshold voltage within the memory die, the register transfer component 630 may be configured as or otherwise support a means for transferring the indication directly from the first register to the second register.

In some examples, the command reception component 645 may be configured as or otherwise support a means for receiving, by the memory die, the command issued by the controller external to the memory die, where the command includes a single command, and where the indication of the minimum threshold voltage is transferred directly from the first register to the second register in response to reception of the single command.

In some examples, the single command includes a get feature command associated with the minimum threshold voltage.

In some examples, the indication of the minimum threshold voltage is transferred directly from the first register to the second register without being transferred to the controller external to the memory die.

In some examples, the first register includes a dedicated register and the second register includes a general purpose register.

In some examples, the described functionality of the memory system 620, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 620, or various components thereof, may be implemented at least in part by instructions (e.g., stored in memory, non-transitory computer-readable medium) executable by such at least one processor.

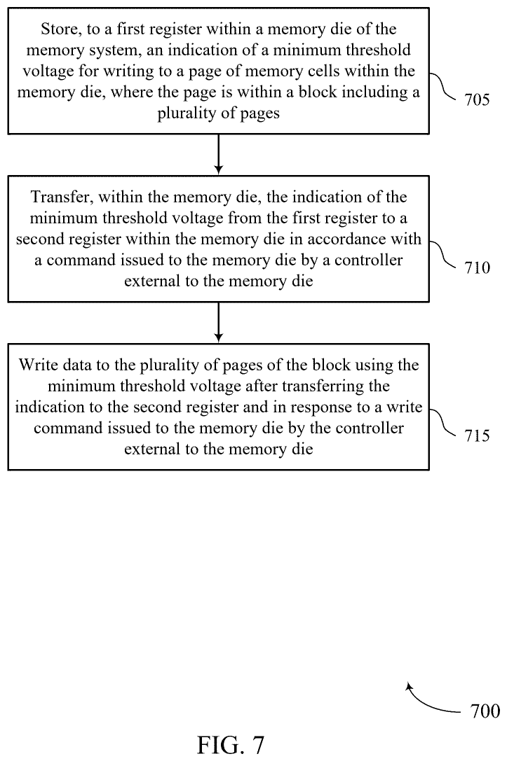

FIG. 7 shows a flowchart illustrating a method 700 that supports word line voltage management for a memory system in accordance with examples as disclosed herein. The operations of method 700 may be implemented by a memory system or its components as described herein. For example, the operations of method 700 may be performed by a memory system as described with reference to FIGS. 1 through 6. In some examples, a memory system may execute a set of instructions to control the functional elements of the device to perform the described functions. Additionally, or alternatively, the memory system may perform aspects of the described functions using special-purpose hardware.

At 705, the method may include storing, to a first register within a memory die of the memory system, an indication of a minimum threshold voltage for writing to a page of memory cells within the memory die, where the page is within a block including a plurality of pages. In some examples, aspects of the operations of 705 may be performed by a register storage component 625 as described with reference to FIG. 6.

At 710, the method may include transferring, within the memory die, the indication of the minimum threshold voltage from the first register to a second register within the memory die in accordance with a command issued to the memory die by a controller external to the memory die. In some examples, aspects of the operations of 710 may be performed by a register transfer component 630 as described with reference to FIG. 6.

At 715, the method may include writing data to the plurality of pages of the block using the minimum threshold voltage after transferring the indication to the second register and in response to a write command issued to the memory die by the controller external to the memory die. In some examples, aspects of the operations of 715 may be performed by a data write component 635 as described with reference to FIG. 6.

In some examples, an apparatus as described herein may perform a method or methods, such as the method 700. The apparatus may include features, circuitry, logic, means, or instructions (e.g., a non-transitory computer-readable medium storing instructions executable by one or more processors), or any combination thereof for performing the following aspects of the present disclosure:

Aspect 1: A method, apparatus, or non-transitory computer-readable medium including operations, features, circuitry, logic, means, or instructions, or any combination thereof for storing, to a first register within a memory die of the memory system, an indication of a minimum threshold voltage for writing to a page of memory cells within the memory die, where the page is within a block including a plurality of pages; transferring, within the memory die, the indication of the minimum threshold voltage from the first register to a second register within the memory die in accordance with a command issued to the memory die by a controller external to the memory die; and writing data to the plurality of pages of the block using the minimum threshold voltage after transferring the indication to the second register and in response to a write command issued to the memory die by the controller external to the memory die.

Aspect 2: The method, apparatus, or non-transitory computer-readable medium of aspect 1, further including operations, features, circuitry, logic, means, or instructions, or any combination thereof for determining the minimum threshold voltage for writing to the page of memory cells within the memory die in response to writing to a first page of a word line within the block, where storing the indication to the first register is in response to determining the minimum threshold voltage.

Aspect 3: The method, apparatus, or non-transitory computer-readable medium of aspect 2, where operations, features, circuitry, logic, means, or instructions, or any combination thereof for determining the minimum threshold voltage includes operations, features, circuitry, logic, means, or instructions, or any combination thereof for determining a minimum quantity of programming pulses for writing to the first page of the word line within the block.

Aspect 4: The method, apparatus, or non-transitory computer-readable medium of any of aspects 1 through 3, further including operations, features, circuitry, logic, means, or instructions, or any combination thereof for receiving, by the memory die, the write command issued by the controller external to the memory die, where the write command includes one or more bits indicating to use the minimum threshold voltage.

Aspect 5: The method, apparatus, or non-transitory computer-readable medium of aspect 4, where the second register is included in a plurality of registers that are each associated with a respective minimum threshold voltage for a respective block type.

Aspect 6: The method, apparatus, or non-transitory computer-readable medium of aspect 5, further including operations, features, circuitry, logic, means, or instructions, or any combination thereof for determining a type of the block in accordance with a first value of the one or more bits indicating to use the minimum threshold voltage for the type of the block.

Aspect 7: The method, apparatus, or non-transitory computer-readable medium of any of aspects 5 through 6, further including operations, features, circuitry, logic, means, or instructions, or any combination thereof for determining, for a second time, the minimum threshold voltage for writing to the page of memory cells within the memory die in accordance with a second value of the one or more bits.

Aspect 8: The method, apparatus, or non-transitory computer-readable medium of any of aspects 1 through 7, where operations, features, circuitry, logic, means, or instructions, or any combination thereof for transferring the indication of the minimum threshold voltage within the memory die includes operations, features, circuitry, logic, means, or instructions, or any combination thereof for transferring the indication directly from the first register to the second register.

Aspect 9: The method, apparatus, or non-transitory computer-readable medium of aspect 8, further including operations, features, circuitry, logic, means, or instructions, or any combination thereof for receiving, by the memory die, the command issued by the controller external to the memory die, where the command includes a single command, and where the indication of the minimum threshold voltage is transferred directly from the first register to the second register in response to reception of the single command.

Aspect 10: The method, apparatus, or non-transitory computer-readable medium of aspect 9, where the single command includes a get feature command associated with the minimum threshold voltage.

Aspect 11: The method, apparatus, or non-transitory computer-readable medium of any of aspects 9 through 10, where the indication of the minimum threshold voltage is transferred directly from the first register to the second register without being transferred to the controller external to the memory die.

Aspect 12: The method, apparatus, or non-transitory computer-readable medium of any of aspects 1 through 11, where the first register includes a dedicated register and the second register includes a general purpose register.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
store, to a first register within a memory die of the memory system, an indication of a minimum threshold voltage for writing to a page of memory cells within the memory die, wherein the page is within a block comprising a plurality of pages;
transfer, within the memory die, the indication of the minimum threshold voltage from the first register to a second register within the memory die in accordance with a command issued to the memory die by a controller external to the memory die; and
write data to the plurality of pages of the block using the minimum threshold voltage after transferring the indication to the second register and in response to a write command issued to the memory die by the controller external to the memory die.

2. The memory system of claim 1, wherein the processing circuitry is further configured to cause the memory system to:
determine the minimum threshold voltage for writing to the page of memory cells within the memory die in response to writing to a first page of a word line within the block, wherein the processing circuitry is configured to cause the memory system to store the indication to the first register in response to determining the minimum threshold voltage.

3. The memory system of claim 2, wherein, to determine the minimum threshold voltage, the processing circuitry is configured to cause the memory system to:
determine a minimum quantity of programming pulses for writing to the first page of the word line within the block.

4. The memory system of claim 1, wherein the processing circuitry is further configured to cause the memory system to:
receive, by the memory die, the write command issued by the controller external to the memory die, wherein the write command comprises one or more bits indicating to use the minimum threshold voltage.

5. The memory system of claim 4, wherein the second register is included in a plurality of registers that are each associated with a respective minimum threshold voltage for a respective block type.

6. The memory system of claim 5, wherein the processing circuitry is further configured to cause the memory system to:
determine a type of the block in accordance with a first value of the one or more bits indicating to use the minimum threshold voltage for the type of the block.

7. The memory system of claim 5, wherein the processing circuitry is further configured to cause the memory system to:
determine, for a second time, the minimum threshold voltage for writing to the page of memory cells within the memory die in accordance with a second value of the one or more bits.

8. The memory system of claim 1, wherein, to transfer the indication of the minimum threshold voltage within the memory die, the processing circuitry is configured to cause the memory system to:
transfer the indication directly from the first register to the second register.

9. The memory system of claim 8, wherein the processing circuitry is further configured to cause the memory system to:
receive, by the memory die, the command issued by the controller external to the memory die, wherein the command comprises a single command, wherein the processing circuitry is configured to cause the memory system to transfer the indication of the minimum threshold voltage directly from the first register to the second register in response to reception of the single command.

10. The memory system of claim 9, wherein the single command comprises a get feature command associated with the minimum threshold voltage.

11. The memory system of claim 9, wherein the processing circuitry is configured to cause the memory system to transfer the indication of the minimum threshold voltage directly from the first register to the second register without being transferred to the controller external to the memory die.

12. The memory system of claim 1, wherein the first register comprises a dedicated register and the second register comprises a general purpose register.

13. A non-transitory computer-readable medium storing code comprising instructions which, when executed by one or more processors of a memory system, cause the memory system to:
store, to a first register within a memory die of the memory system, an indication of a minimum threshold voltage for writing to a page of memory cells within the memory die, wherein the page is within a block comprising a plurality of pages;
transfer, within the memory die, the indication of the minimum threshold voltage from the first register to a second register within the memory die in accordance with a command issued to the memory die by a controller external to the memory die; and
write data to the plurality of pages of the block using the minimum threshold voltage after transferring the indication to the second register and in response to a write command issued to the memory die by the controller external to the memory die.

14. The non-transitory computer-readable medium of claim 13, wherein the instructions, when executed by the one or more processors of the memory system, further cause the memory system to:
determine the minimum threshold voltage for writing to the page of memory cells within the memory die in response to writing to a first page of a word line within the block, wherein the instructions, when executed by the one or more processors of the memory system, further cause the memory system to store the indication to the first register in response to determining the minimum threshold voltage.

15. The non-transitory computer-readable medium of claim 14, wherein, to determine the minimum threshold voltage, the instructions, when executed by the one or more processors of the memory system, cause the memory system to:
determine a minimum quantity of programming pulses for writing to the first page of the word line within the block.

16. The non-transitory computer-readable medium of claim 13, wherein the instructions, when executed by the one or more processors of the memory system, further cause the memory system to:
receive, by the memory die, the write command issued by the controller external to the memory die, wherein the write command comprises one or more bits indicating to use the minimum threshold voltage.

17. The non-transitory computer-readable medium of claim 16, wherein the second register is included in a plurality of registers that are each associated with a respective minimum threshold voltage for a respective block type.

18. The non-transitory computer-readable medium of claim 17, wherein the instructions, when executed by the one or more processors of the memory system, further cause the memory system to:
determine a type of the block in accordance with a first value of the one or more bits indicating to use the minimum threshold voltage for the type of the block.

19. The non-transitory computer-readable medium of claim 17, wherein the instructions, when executed by the one or more processors of the memory system, further cause the memory system to:
determine, for a second time, the minimum threshold voltage for writing to the page of memory cells within the memory die in accordance with a second value of the one or more bits.

20. The non-transitory computer-readable medium of claim 13, wherein, to transfer the indication of the minimum threshold voltage within the memory die, the instructions, when executed by the one or more processors of the memory system, cause the memory system to:
transfer the indication directly from the first register to the second register.

21. The non-transitory computer-readable medium of claim 20, wherein the instructions, when executed by the one or more processors of the memory system, further cause the memory system to:
receive, by the memory die, the command issued by the controller external to the memory die, wherein the command comprises a single command, wherein the instructions, when executed by the one or more processors of the memory system, cause the memory system to transfer the indication of the minimum threshold voltage directly from the first register to the second register in response to reception of the single command.

22. The non-transitory computer-readable medium of claim 21, wherein the single command comprises a get feature command associated with the minimum threshold voltage.

23. The non-transitory computer-readable medium of claim 21, wherein the instructions, when executed by the one or more processors of the memory system, cause the memory system to transfer the indication of the minimum threshold voltage directly from the first register to the second register without being transferred to the controller external to the memory die.

24. The non-transitory computer-readable medium of claim 13, wherein the first register comprises a dedicated register and the second register comprises a general purpose register.

25. A method by a memory system, comprising:
storing, to a first register within a memory die of the memory system, an indication of a minimum threshold voltage for writing to a page of memory cells within the memory die, wherein the page is within a block comprising a plurality of pages;
transferring, within the memory die, the indication of the minimum threshold voltage from the first register to a second register within the memory die in accordance with a command issued to the memory die by a controller external to the memory die; and
writing data to the plurality of pages of the block using the minimum threshold voltage after transferring the indication to the second register and in response to a write command issued to the memory die by the controller external to the memory die.
